(19) United States
(12) Patent Application Publication
(10) Pub. No.: US 2025/0357120 A1
(43) Pub. Date: Nov. 20, 2025

(54) MANUFACTURING METHOD OF SEMICONDUCTOR DEVICE INCLUDING PLASMA ETCHING PROCESS

(71) Applicant: Samsung Electronics Co., Ltd., Suwon-si (KR)

(72) Inventors: Buseo Choi, Suwon-si (KR); Thanh Cuong Nguyen, Suwon-si (KR); Heejeong Kim, Suwon-si (KR); Wonwoong Chung, Suwon-si (KR); Younjoung Cho, Suwon-si (KR); Jaesik An, Suwon-si (KR); Suntaek Lim, Suwon-si (KR); Seungmin Lee, Suwon-si (KR); Inkook Jang, Suwon-si (KR)

(21) Appl. No.: 19/034,919

(22) Filed: Jan. 23, 2025

(30) Foreign Application Priority Data
May 20, 2024 (KR) 10-2024-0065360

(51) Int. Cl. H01L 21/033; H01L 21/311; H01L 21/3213

(52) U.S. Cl. CPC H01L 21/0337; H01L 21/31144; H01L 21/32139

(57) ABSTRACT

A method of manufacturing a semiconductor device includes forming a mask pattern on a feature layer, modifying a surface of the mask pattern by using a plasmafied metal precursor gas to provide a modified surface, and etching the feature layer by using the mask pattern with the modified surface.

### CROSS-REFERENCE TO RELATED APPLICATION

This application is based on and claims priority under 35 U.S.C. § 119 to Korean Patent Application No. 10-2024-0065360, filed on May 20, 2024, in the Korean Intellectual Property Office, the disclosure of which is incorporated by reference herein in its entirety.

### BACKGROUND

The inventive concept relates to a method of manufacturing a semiconductor device, and more particularly, a method of manufacturing a semiconductor device that includes a plasma etching process.

As semiconductor devices are highly integrated, critical dimensions (CD) of patterns formed on semiconductor substrates are decreasing. Accordingly, a process of forming fine patterns on a semiconductor substrate may be used. A plasma etching process may be introduced to form fine patterns on a semiconductor substrate.

However, pattern realization may be insufficient because of insufficient etching resistance of the etching mask.

### SUMMARY

The inventive concept provides a method of manufacturing a semiconductor device that includes a plasma etching process with improved reliability.

According to an aspect of the inventive concept, there is provided a method of manufacturing a semiconductor device. The method includes forming a mask pattern on a feature layer, modifying a surface of the mask pattern by using a plasmafied metal precursor gas to form a modified surface, and etching the feature layer by using the mask pattern having the modified surface.

According to an aspect of the inventive concept, there is provided a method of manufacturing a semiconductor device. The method includes forming a feature layer on a substrate, forming a mask pattern on the feature layer, modifying a surface of the mask pattern with a metal, and forming a feature pattern by removing a portion of the feature layer using a gas mixture that is plasmafied, wherein the gas mixture includes an etching gas and a metal precursor gas.

According to an aspect of the inventive concept, there is provided a method of manufacturing a semiconductor device. The method includes forming a mask pattern on a feature layer, modifying a surface of the mask pattern with a first metal precursor gas that is plasmafied, forming a feature pattern by a gas mixture including an etching gas and a second metal precursor gas into a plasma and removing a portion of the feature layer by using the mask pattern as an etch mask, forming, on an inner sidewall of the feature pattern and the surface of the mask pattern, a fluorocarbon-based passivation layer including a carbon-metal bond, and removing the mask pattern and the passivation layer, wherein the removing of the portion of the feature layer temporally overlaps the forming of the passivation layer.

### BRIEF DESCRIPTION OF THE DRAWINGS

Embodiments will be more clearly understood from the following detailed description taken in conjunction with the accompanying drawings in which:

FIG. 1A is a schematic cross-sectional view of a plasma etching device used for a method of manufacturing a semiconductor device, according to some embodiments;

FIG. 1B is a schematic cross-sectional view of a plasma etching device used for a method of manufacturing a semiconductor device, according to some embodiments;

FIG. 2 is a flowchart illustrating a method of manufacturing a semiconductor device, according to some embodiments;

FIG. 3 is a plan view of a semiconductor device illustrating a method of manufacturing a semiconductor device, according to some embodiments;

FIGS. 4A to 4D are cross-sectional views shown in process sequence illustrating a method of manufacturing a semiconductor device according to some embodiments, the cross-sectional views showing, in process sequence, a portion corresponding to a cross-section taken along a line X1-X1′ of FIG. 3;

FIG. 5 is a cross-sectional view illustrating a method of manufacturing a semiconductor device according to some embodiments, the cross-sectional view showing a portion corresponding to the cross-section taken along the line X1-X1′ of FIG. 3; and

FIGS. 6A to 6D are cross-sectional views shown in process sequence illustrating a method of manufacturing a semiconductor device according to some embodiments, the cross-sectional views showing, in process sequence, a portion corresponding to the cross-section taken along the line X1-X1′ of FIG. 3.

### DETAILED DESCRIPTION OF THE EMBODIMENTS

Hereinafter, one or more embodiments of the inventive concept are described in detail with reference to the attached drawings. Like reference numerals in the drawings denote like elements, and repeated descriptions thereof will be omitted.

In the present specification, the vertical direction may be defined as a Z direction, and the horizontal direction may be defined as a direction perpendicular to the Z direction. The first horizontal direction and the second horizontal direction may be defined as crossing each other. The first horizontal direction may be referred to as an X direction, while the second horizontal direction may be referred to as a Y direction. The vertical level may refer to a height level in the vertical direction (the Z direction).

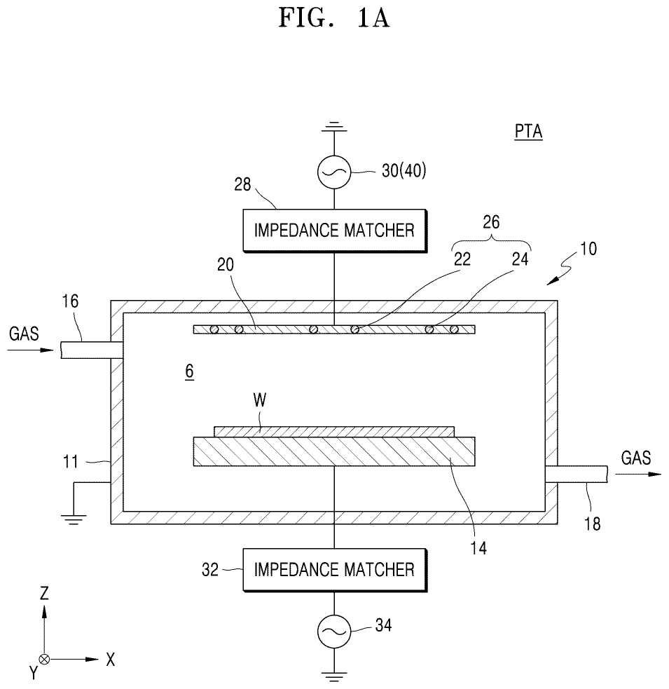

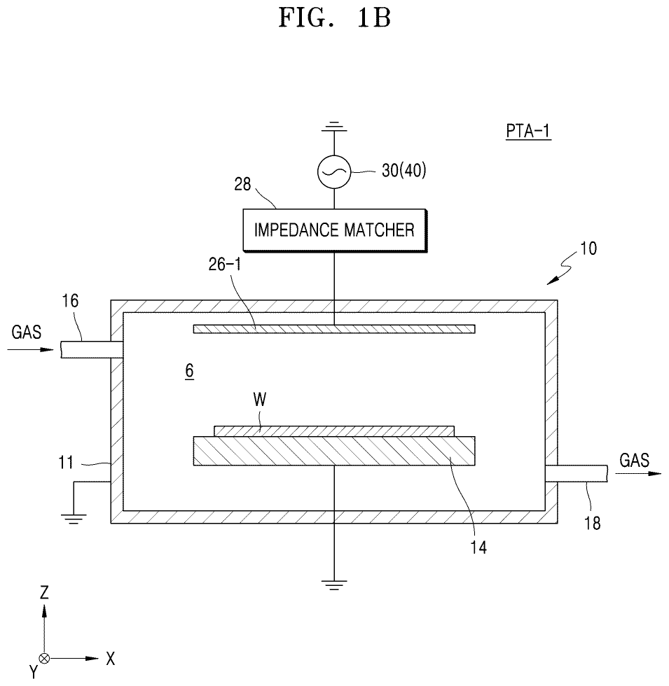

FIG. 1A is a schematic cross-sectional view of a plasma etching device PTA used for a method of manufacturing a semiconductor device, according to some embodiments.

According to some embodiments, the plasma etching device PTA may include a process chamber 10 on which a gas injection portion 16 and a gas discharge portion 18 are installed.

According to some embodiments, the process chamber 10 may have an inner space 6 providing a space where plasma etching is to be performed. According to some embodiments, in the process chamber 10, a process gas, for example, an etching gas, may be injected through the gas injection portion 16 and may be discharged to the outside through the gas discharge portion 18. The process chamber 10 may be maintained at a high vacuum to prevent process defects that may be caused by contaminants, for example, particles, during plasma etching. In some embodiments, the process chamber 10 may be grounded.

According to some embodiments, the process chamber 10 may include a high-frequency electrode unit 26 and an electrostatic chuck 14 located in the inner space 6. The high-frequency electrode unit 24 and the electrostatic chuck 14 may face each other and may be used as a first electrode and a second electrode, respectively. According to some embodiments, the high-frequency electrode unit 26 may be installed on a dielectric window 20 on an upper portion of the process chamber 10.

According to some embodiments, the high-frequency electrode unit 26 may include a plurality of high-frequency antennas 22 and 24. In some embodiments, the high-frequency antennas 22 and 24 may include an internal antenna 22 corresponding to a central portion of a wafer W and an external antenna 24 located outside the internal antenna 22 and corresponding to an edge portion of the wafer W. For example, the internal antenna 22 may overlap the central portion of the wafer W in the vertical direction (the Z direction). For example, at least a portion of the external antenna 24 may overlap the edge portion of the wafer W in the vertical direction (the Z direction).

According to some embodiments, a high-frequency power source 30 may be connected to the high-frequency electrode unit 26, and high-frequency power (power) may be applied to the high-frequency electrode unit 26 through an impedance matcher 28. For example, the high-frequency power may include radio frequency (RF) power.

In some embodiments, the high-frequency power applied through the high-frequency power source 30 may be power with a frequency of about 27 MHz or higher. For example, the high-frequency power applied through the high-frequency power source 30 may be power with a frequency of about 60 MHz. In some embodiments, the high-frequency antennas 22 and 24 may include the internal antenna 22 and the external antenna 24 and finely control the magnetic field, thus enabling uniform plasma density on the wafer W.

According to some embodiments, the electrostatic chuck 14 may be configured to support the wafer W. For example, the wafer W may include a silicon substrate, but is not limited thereto. In some embodiments, the electrostatic chuck 14 may be connected to a bias power source 34, and high-frequency power may be applied to the electrostatic chuck 14 from the bias power source 34 through an impedance matcher 32. The impedance matcher 32 may be connected to the bias power source 34. In some embodiments, the plasma etching device PTA may be an inductively coupled plasma (ICP) etching device.

In some embodiments, the high-frequency power applied through the bias power source 34 may be power with a frequency in a range from about 100 KHz to about 10 MHZ, but one or more embodiments are not limited thereto. In some embodiments, the impedance matchers 28 and 32 may be omitted.

According to some embodiments, the process gas, that is, the etching gas, which is injected into the process chamber 10, may be turned into plasma by a plasma generator 40. The plasma generator 40 may include the high-frequency power source 30 electrically connected to the high-frequency electrode unit 26.

When power is supplied to the high-frequency electrode unit 26 through the high-frequency power source 30, the process gas injected into the process chamber 10 may be converted into plasma. When high-frequency power or low-frequency power is supplied to the electrostatic chuck 14 through the bias power source 34, the plasma generated in the process chamber 10 may be accelerated by bias and guided towards the wafer W.

FIG. 1B is a schematic cross-sectional view of a plasma etching device PTA-1 used for a method of manufacturing a semiconductor device, according to some embodiments.

The plasma etching device PTA-1 described with reference to FIG. 1B may be the same as the plasma etching device PTA of FIG. 1A except that the plasma etching device PTA-1 includes a high-frequency electrode unit 26-1 including a plate electrode and the electrostatic chuck 14 is grounded. In FIG. 1B, like reference numerals as in FIG. 1A denote like elements, and repeated descriptions thereof are omitted.

According to some embodiments, the plasma etching device PTA-1 may include the high-frequency electrode unit 26-1 and the electrostatic chuck 14 that are arranged in the process chamber 10. A plate electrode may be used as the high-frequency electrode unit 26-1 of the plasma etching device PTA-1. In some embodiments, the plasma etching device PTA-1 may be a charge coupled plasma (CCP) etching device.

According to some embodiments, the process gas, that is, the etching gas, which is injected into the process chamber 10, may be converted into plasma by the plasma generator 40. The plasma generator 40 may include the high-frequency power source 30 electrically connected to the high-frequency electrode unit 26-1. When power is supplied to the high-frequency electrode unit 26-1 through the high-frequency power source 30, the process gas injected into the process chamber 10 may be converted into plasma.

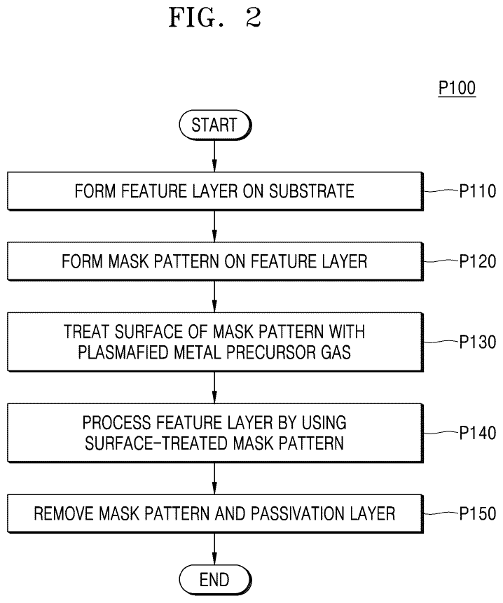

FIG. 2 is a flowchart illustrating a method of manufacturing a semiconductor device according to some embodiments, the method including a plasma etching process.

Referring to FIG. 2, a method P100 of manufacturing a semiconductor device that includes a plasma etching process may include operation P110 of forming a feature layer on a first surface of a substrate, operation P120 of forming a mask pattern on the feature layer, operation P130 of treating or modifying a surface of the mask pattern by using a plasmafied metal precursor gas, operation P140 of processing the feature layer by using the surface-treated mask pattern, and operation P150 of removing the mask pattern and a passivation layer formed during the processing. When the feature layer is processed in operation P140 and the mask pattern is removed in operation P150, then a feature pattern may be used using the plasmafied metal precursor gas.

An additional process may be performed between two consecutive operations of the method P100 of manufacturing a semiconductor device, the method being shown in the flowchart of FIG. 2. For example, cleaning or additional chemical processing may be performed after operation P120 of forming the mask pattern on the feature layer and before operation P130 of treating the surface of the mask pattern or after operation P140 of processing the feature layer, but one or more embodiments are not limited thereto.

Technical features of each operation of the method P100 of manufacturing a semiconductor device that includes the plasma etching process described above are described below in more detail with reference to FIGS. 2 to 4D together.

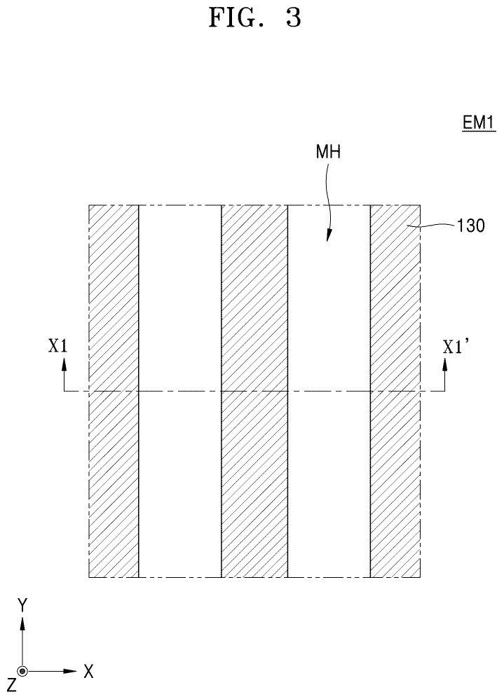

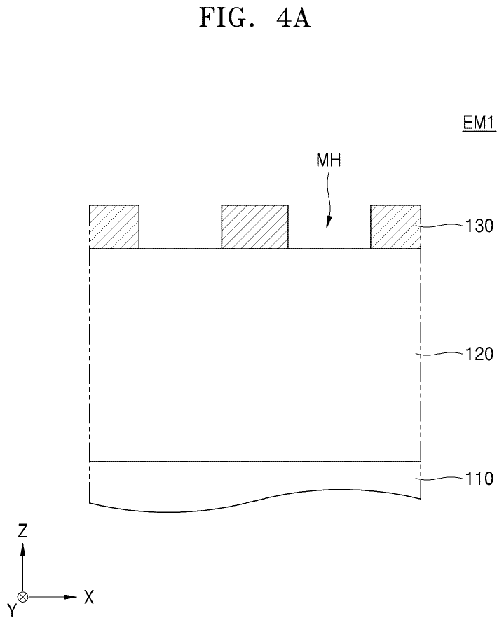

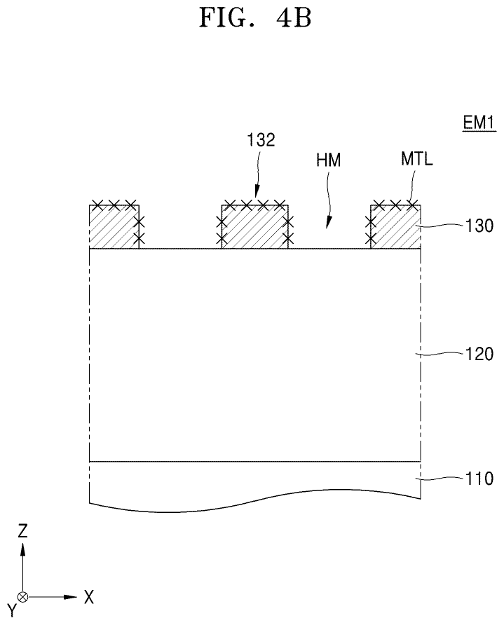

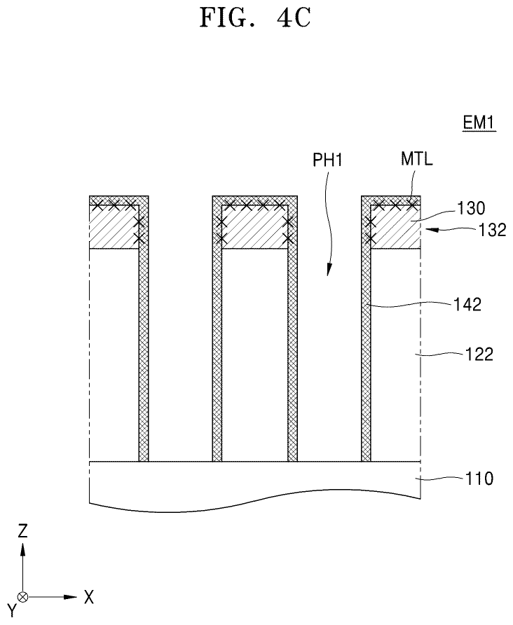

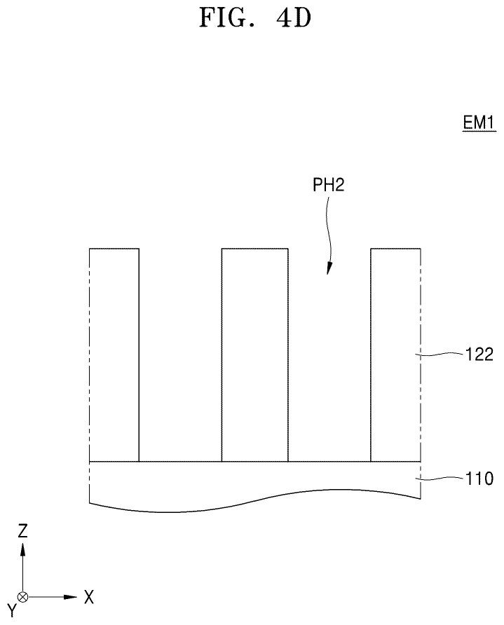

FIG. 3 is a plan view of a semiconductor device EM1 illustrating a method of manufacturing a semiconductor device, according to some embodiments. FIGS. 4A to 4D are cross-sectional views shown in process sequence illustrating a method of manufacturing the semiconductor device EM1 according to some embodiments, the cross-sectional views showing, in process sequence, a portion corresponding to a cross-section taken along a line X1-X1′ of FIG. 3. In detail, FIG. 4A is a cross-sectional view taken along the line X1-X1′ of FIG. 3, and FIG. 3 is a plan view of the semiconductor device EM1 in the first operation of the method of manufacturing the semiconductor device EM1.

Referring to FIGS. 2, 3, and 4A together, after operation P110 of forming a feature layer 120 on the first surface of the substrate 110, a mask pattern 130 may be formed on the feature layer 120 in operation P120.

In some embodiments, the substrate 110 may include a semiconductor such as silicon (Si) or germanium (Ge) or a compound semiconductor such as silicon germanium (SiGe), silicon carbide (SiC), gallium arsenide (GaAs), indium arsenide (InAs), InGaAs, or indium phosphide (InP). The terms such as “SiGe,” “SiC,” “GaAs,” “InAs,” “InGaAs,” and “InP” used in the specification refer to materials containing elements included in each term and do not represent chemical formulas indicating stoichiometric relationships. In some embodiments, the substrate 110 may have a bulk Si substrate or a silicon-on-insulator (SOI) structure. In some embodiments, the substrate 110 may include a conductive area, for example, a well doped with impurities or a structure doped with impurities.

According to some embodiments, operation P110 of forming the feature layer 120 may include s deposition on the first surface of the substrate 110. In some embodiments, atomic layer deposition (ALD), chemical vapor deposition (CVD), plasma-enhanced CVD (PECVD), physical vapor deposition (PVD), reactive pulsed laser deposition, or a combination thereof may be used to form the feature layer 120.

In some embodiments, the feature layer 120 may include metal, alloys, metal carbide, metal nitride, metal oxynitride, metal oxycarbide, semiconductors, polysilicon, oxide, nitride, oxynitride, or a combination thereof.

In some embodiments, the feature layer 120 may include an insulating material based on Si. For example, the feature layer 120 may include silicon oxide, silicon nitride, silicon oxynitride, or a combination thereof.

According to some embodiments, operation P120 of forming the mask pattern 130 on the feature layer 120 may include photolithography. In some embodiments, the mask pattern 130 may include a carbon-based material, for example, an amorphous carbon layer (ACL) or a metal-doped carbon layer. In some embodiments, the mask pattern 130 may include a silicon-based material, for example, polysilicon or silicon doped with metal.

In some embodiments, a mask hole MH may be defined by the mask pattern 130. For example, the mask hole MH may be limited by an inner sidewall of the mask pattern 130 and an upper surface of a portion of the feature layer 120 that does not vertically overlap the mask pattern 130. FIGS. 3 and 4A show that the mask pattern 130 extends in the second horizontal direction (the Y direction) and the mask hole MH has a plurality of trench shapes extending in the second horizontal direction (the Y direction), but embodiments of the present inventive concept are not limited thereto. For example, the shape of the mask pattern 130 may be a perforated plate, and the mask hole MH may have a plurality of dots spaced apart from each other.

Referring to FIGS. 2 and 4B, in the result of FIG. 4A, the surface of the mask pattern 130 may be modified with a metal. According to some embodiments, in operation P130, the surface of the mask pattern 130 may be processed using a first metal precursor gas that is plasmafied.

In some embodiments, the plasma etching devices PTA and PTA-1 described with reference to FIGS. 1A and 1B may be used to convert the first metal precursor gas into plasma. The semiconductor device EM1 of FIG. 4B and a semiconductor device EM1 described below with reference to FIG. 4C according to the process order illustrating the method of manufacturing the semiconductor device EM1 may correspond to the wafer W of FIGS. 1A and 1B.

According to some embodiments, the plasmafied first metal precursor gas may be guided to the surface of the mask pattern 130, and metal atoms MTL from a first metal precursor may be chemically bonded to the surface of the mask pattern 130. For example, the metal atoms MTL may be bonded to the upper surface and the inner sidewall of the mask pattern 130. For example, the surface of the mask pattern 130 may be modified with a metal by using the plasmafied first metal precursor gas. In the present specification, a thin layer including the metal atoms MTL bonded to the mask pattern 130 may be referred to as a surface modification layer. For example, the inner wall of the mask hole MH may be coated with the surface modification layer. In some embodiments, by processing the surface of the mask pattern 130, a modified mask pattern 132 including the metal particles MTL may be formed.

The surface modification layer may be formed on the surface of the mask pattern 130, and the surface-treated mask pattern 130 may exhibit excellent etching resistance during the plasma etching process described below. A method of manufacturing a semiconductor device without forming a surface modification, for example, as illustrated in the Comparative Example described herein, has a problem in which, as a result of performing plasma etching without forming a surface modification layer, at least a portion of the mask pattern 130 is removed, resulting in insufficient etch selectivity. For example, as illustrated in the Comparative Example below, the loss of the mask pattern 130 due to plasma etching may lead to a non-uniform feature pattern.

In some embodiments, the metal of the first metal precursor gas may include titanium (Ti), zirconium (Zr), hafnium (Hf), vanadium (V), niobium (Nb), tantalum (Ta), molybdenum (Mo), tungsten (W), or a combination thereof. In some embodiments, the oxidation number of the central metal in the metal precursor may be between 0 and 4, and the metal precursor may include a ligand bonded to the central metal. In some embodiments, the ligand may include a halogen ligand or an organic ligand.

In some embodiments, the titanium precursor may include titanium chloride and titanium bromide including halogen ligands, bis(cyclopentadienyl) titanium dichloride and titanium tetraiodide including alkyl ligands, titanium isopropoxide and titanium ethoxide including alkoxy ligands, and tetrakis(dimethylamido)titanium and tetrakis(diethylamido)titanium including amino ligands.

In some embodiments, the zirconium precursor may include zirconium chloride and zirconium fluoride including halogen ligands, bis(cyclopentadienyl)zirconium dichloride and bis(cyclopentadienyl)zirconium chloride hydride including alkyl ligands, zirconium tert-butoxide and tetrakis(2,4-pentanedionato)zirconium including alkoxy ligands, and tetrakis(dimethylamido)zirconium and tetrakis(ethylmethylamido)zirconium including amino ligands.

In some embodiments, the hafnium precursor may include hafnium chloride and hafnium fluoride including halogen ligands, bis(cyclopentadienyl)hafnium dichloride and tetrabenzyl hafnium including alkyl ligands, hafnium trifluoromethanesulfonate and hafnium 2,4-pentanedionate including alkoxy ligands, and tetrakis(dimethylamido)hafnium and tetrakis(ethylmethylamido)hafnium including amino ligands.

In some embodiments, the vanadium precursor may include vanadium chloride and vanadium fluoride including halogen ligands, vanadium tris(acetylacetonato) and vanadium tetrabenzyl including alkyl ligands, vanadium ethoxide and vanadium isopropoxide including alkoxy ligands, and vanadium tris(dimethylamido) and vanadium tetrakis(ethylmethylamido) including amino ligands.

In some embodiments, the niobium precursor may include niobium chloride and niobium fluoride including halogen ligands, niobium ethoxide and cyclopentadienylniobium tetrachloride including alkyl ligands, tetrakis(2,2,6,6-tetramethyl-3,5-heptanedionato)niobium and tetrachlorobis(tetrahydrofuran)niobium including alkoxy ligands, and pentakis(dimethylamino)niobium and tris(diethylamido)(tert-butylimido)niobium including amino ligands.

In some embodiments, the tantalum precursor may include tantalum chloride and tantalum fluoride including halogen ligands, tantalum ethoxide and tantalum tetracthoxide 2,4-pentanedionate including alkoxy ligands, and tris(diethylamido)(tert-butylimido)tantalum and pentakis(dimethylamino)tantalum including amino ligands.

In some embodiments, the molybdenum precursor may include molybdenum chloride and molybdenum chloride including halogen ligands, molybdenum hexacarbonyl and bis(ethylcyclopentadienyl)molybdenum dichloride including alkyl ligands, molybdenum ethoxide and tris(t-butoxy)(2,2-dimethylpropylidyne)molybdenum including alkoxy ligands, and bis(tert-butylimino)bis(dimethylamino)molybdenum including amino ligands.

In some embodiments, the tungsten precursor may include tungsten chloride and tungsten chloride including halogen ligands, tungsten hexacarbonyl and bis(ethylcyclopentadienyl)tungsten dichloride including alkyl ligands, tungsten ethoxide and tris(t-butoxy)(2,2-dimethylpropylidyne)tungsten including alkoxy ligands, and bis(tert-butylimino)bis(dimethylamino)tungsten including amino ligands.

In some embodiments, the mask pattern 130 may include a carbon-based material, for example, an ACL or a metal-doped carbon layer, and the metal of the surface modification layer may include Ti, Zr, Hf, V, Nb, Ta, Mo, W, or a combination thereof.

In some embodiments, the mask pattern 130 may include a silicon-based material, for example, polysilicon or silicon doped with metal, and the metal of the surface modification layer may include Zr, Hf, Nb, Ta, Mo, W, or a combination thereof.

Referring to FIGS. 2 and 4C, in the result of FIG. 4B, a feature layer may be processed using the surface-treated mask pattern 130 in operation P140. According to some embodiments, the plasma etching process may be performed to process the feature layer, and the plasma etching devices PTA and PTA-1 described with reference to FIGS. 1A and 1B may be used.

According to some embodiments, a portion of the feature layer 120 (see FIG. 4B) may be removed through plasma etching using the plasmafied etching gas, thus forming a feature pattern 122. The mask pattern 130 and the surface modification layer including the metal particles MTL may be provided as etch masks. In some embodiments, the plasma etching may be performed so that the first surface of the substrate 110 is partially exposed.

According to some embodiments, the processing of the feature layer 120 may include forming, on the exposed surface, a passivation layer 142 derived from the components of the etching gas. In some embodiments, the passivation layer 142 may be formed on the upper surface and the inner sidewall of the mask pattern 130 and the inner sidewall of the feature pattern 122. In some embodiments, the passivation layer 142 may be formed on the surface modification layer. For example, the passivation layer 142 may be formed to cover the metal particles MTL.

In some embodiments, the partial removal of the feature layer 120 may temporally overlap the formation of the passivation layer 142. For example, the passivation layer 142 may be simultaneously formed to cover the surface of the mask pattern 130 and the exposed inner wall of the feature layer 120 as a portion of the feature layer 120 is removed.

In some embodiments, a first pattern hole PH1 defined by the first surface of the substrate 110 and the passivation layer 142 on the inner sidewall of the feature pattern 122 may be defined.

In some embodiments, the etching gas may include fluorocarbon, hydrofluorocarbon, a fluorine-based material containing core elements other than carbon, or a combination thereof.

In some embodiments, the fluorocarbon may be represented by the chemical formula CₓF_{y} where 1≤x≤5 and 4≤y≤2x+2. For example, the fluorocarbon may include CF₄, C₂F₆, C₃F₆, C₄F₆, C₄F₈, or a combination thereof.

In some embodiments, the hydrofluorocarbon may be represented by the chemical formula CxHyFz, where 1≤x≤5, 1≤y≤2x+1, 1≤z≤2x+1, and 4≤y+z≤2x+2. For example, the hydrofluorocarbon may include CHF₃, CH₂F₂, CH₃F, C₂H₂F₄, or a combination thereof.

In some embodiments, the fluorine-based material including core elements other than carbon may include NF₃, SF₆, PF₅, PF₃, BF₃, F₂, HF, or a combination thereof.

In some embodiments, the passivation layer 142 may include a fluorocarbon-based polymer including C—C, C—F, and C—H bonds. The passivation layer 142 may be formed on the surface of the mask pattern 130, more specifically, on the surface of the surface modification layer and the inner sidewall of the feature pattern 122, thus improving line edge roughness (LER) or line width roughness (LWR) of the feature pattern 122 and achieving excellent etch selectivity between the mask pattern 130 and the feature layer 120 (see FIG. 4B).

In some embodiments, the etching gas may further include an inert gas. For example, the inert gas may include at least one selected from among argon (Ar), helium (He), neon (Ne), nitrogen (N₂), krypton (Kr), and xenon (Xe).

In some embodiments, the etching gas may further include a reactive gas. For example, the reactive gas may include at least one selected from among oxygen (O₂), ozone (O₃), carbon monoxide (CO), carbon dioxide (CO₂), carbonyl chloride (COCl₂), carbonyl fluoride (COF₂), nitric oxide (NO), nitrogen dioxide (NO₂), and ammonia (NH₃).

Referring to FIGS. 2 and 4D, in operation P150, the passivation layer 142, the surface modification layer including the metal particles MTL, and the mask pattern 130 may be removed from the result of FIG. 4C.

According to some embodiments, as the passivation layer 142 is removed, the inner sidewall of the feature pattern 122 may be exposed, and a second pattern hole PH2 defined by the inner sidewall of the feature pattern 122 and a portion of the first surface of the substrate 110 may be formed.

In some embodiments, the passivation layer 142 and the mask pattern 130 may be removed through ashing under a high-temperature O₂-containing atmosphere. In this case, the surface modification layer including the metal particles MTL may also be removed. In some embodiments, a cleaning process and an etch-back process may be additionally performed to remove the mask pattern 130, but one or more embodiments are not limited thereto.

The method of manufacturing a semiconductor device that includes a plasma etching process may include forming a surface modification layer by modifying the surface of the mask pattern 130 before a main plasma etching process. The surface modification layer may include metal materials with excellent etching resistance to protect the mask pattern 130. An etching model may be used as a criterion for etching resistance, in which metal atoms on the surface are desorbed due to energy generated by ion collision during reactive ion etching (RIE). The metal of the first metal precursor gas may include a material with a relatively low sputtering yield in the etching model. However, such etching resistance assumes that the surface modification layer is properly formed and requires that the formation energy for bonding metal to a material forming a mask is sufficiently great.

As a factor for confirming whether the surface modification layer is bonded to/formed on the mask pattern 130 and exhibits excellent etching resistance, the stabilization constant Kₛ represented by Equation 1 below may be defined.

$${K}_{s} = Formation energy / sputtering yield \qquad Equation 1$$

In the present specification, the Experimental Example including specific embodiments and comparative examples is presented to help the understanding of the inventive concept; however, this is only an example, and embodiments according to the present inventive concept are not limited thereto.

### Experimental Example 1

In operation P130, the bond formation energy for each metal type with respect to the mask pattern 130 was calculated to determine whether the metal particles MTL are properly bonded to the surface of the mask pattern 130. In operation P140, the sputtering yield of a modified mask pattern 132 was calculated to check whether the modified mask pattern 132 has sufficient etching resistance. The bond formation energy and the sputtering yield were each calculated through simulation, and based on the calculation, the stabilization constant Kₛ was obtained.

The formation energy was obtained through a first principles calculation based on Density Functional Theory (DFT). Here, the first principles calculation refers to calculation using the fundamental equation according to Equation 2 below without using external parameters.

$${E}_{F} = {E}_{Substrate} + {E}_{Metal} - {E}_{substrate - Metal} \qquad Equation 2$$

E_{F}=formation energy
E_{Substrate}=the total energy of mask or polymer materials
E_{Metal}=the total energy of single metal atom
E_{substrate-Metal}=the total energy of mask/polymer-metal complex

For the DFT calculation, the first-principles DFT code, Gaussian16 code, was used, and B3LYP was used as a functional. As the basis set, 6-31G** was used for typical elements (e.g., H, C, F, Si, O, N, and the like), while LANL2DZ was used for metal elements (e.g., Zr, Hf, Nb, and the like).

The sputtering yield was calculated using the same DFT calculation described above, employing Equation 3 and Equation 4.

$$sputtering yield = 1 / cohesive enery \qquad Equation 3$$

Here, Cohesive energy (E_{coh}) may be calculated using Equation 4 below for a material including AₓB_{y}C_{z}.

$${E}_{c o h} = [ x E ( A ) + y E ( B ) + z E ( C ) - E ( {A}_{x} {B}_{y} {C}_{z} ) ] / ( x + y + z ) \qquad Equation 4$$

Here, E_{coh} refers to cohesive energy, E(A) refers to energy when only the atom A independently exists, E(B) refers to energy when only the atom B independently exists, E(C) refers to energy when only the atom C independently exists, and E(AₓB_{y}C_{z}) refers to energy of materials represented by the chemical formula AₓB_{y}C_{z}. For example, E(AₓB_{y}C_{z}) refers to the material energy of the mask pattern 130, the surface modification layer, the passivation layer, and the like represented by the chemical formula AₓB_{y}C_{z}.

The simulation was performed by modeling the process in which the feature layer 120 including SiO₂ is etched by using the ACL as the mask pattern 130 and CF₄ as the etching gas. Table 1 below shows the results from the simulation, including the bond formation energy of metals to the ACL, the sputtering yield of the surface-treated ACL, and the stabilization constant Kₛ when the ACL is used as the mask pattern 130.

TABLE 1

| | | Formation energy | Sputtering | Stabilization |
|---|---|---|---|---|
| | Metals | (eV) | yield | constant Ks |
| Embodiment 1 | Ti | 5.05 | 0.1447 | 34.8998 |
| Embodiment 2 | Zr | 6.77 | 0.1436 | 47.1448 |
| Embodiment 3 | Hf | 6.76 | 0.1432 | 47.2067 |
| Embodiment 4 | V | 3.07 | 0.1445 | 21.2457 |
| Embodiment 5 | Nb | 5.24 | 0.1432 | 36.5921 |
| Embodiment 6 | Ta | 5.42 | 0.1439 | 37.6650 |
| Embodiment 7 | Mo | 3.66 | 0.1444 | 25.3463 |
| Embodiment 8 | W | 4.7 | 0.1442 | 32.5936 |
| Comparative | — | — | 0.1449 | — |
| Example 1 | | | | |

Referring to Table 1, compared to an ACL of Comparative Example 1 that does not include a surface modification layer, it was found that the modified ACL in Embodiment 1 to Embodiment 8 has a relatively low sputtering yield and thus exhibits relatively high etching resistance.

### Experimental Example 2

Except that W-doped Si is used as the mask pattern 130, the simulation was performed under the same conditions as in Experimental Example 1, and the result shown in Table 2 was obtained.

TABLE 2

| | | Formation energy | Sputtering | Stabilization |
|---|---|---|---|---|
| | Metals | (eV) | yield | constant Ks |
| Embodiment 10 | Ti | 5.34 | 0.1469 | 36.3512 |
| Embodiment 11 | Zr | 6.95 | 0.1459 | 47.6354 |
| Embodiment 12 | Hf | 6.28 | 0.1459 | 43.0432 |
| Embodiment 13 | V | 4.57 | 0.1473 | 31.0251 |
| Embodiment 14 | Nb | 5.85 | 0.1459 | 40.0959 |
| Embodiment 15 | Ta | 7.15 | 0.1453 | 49.2085 |
| Embodiment 16 | Mo | 5.35 | 0.1466 | 36.4939 |
| Embodiment 17 | W | 6.68 | 0.1455 | 45.9106 |
| Comparative | — | — | 0.1469 | — |
| Example 2 | | | | |

Referring to Table 2, compared to W-doped Si in Comparative Example 2, which does not include a surface modification layer, it was identified that the modified ACL in Embodiment 11 and Embodiment 12 and Embodiment 14 to Embodiment 17 has a relatively low sputtering yield and thus exhibits relatively high etching resistance.

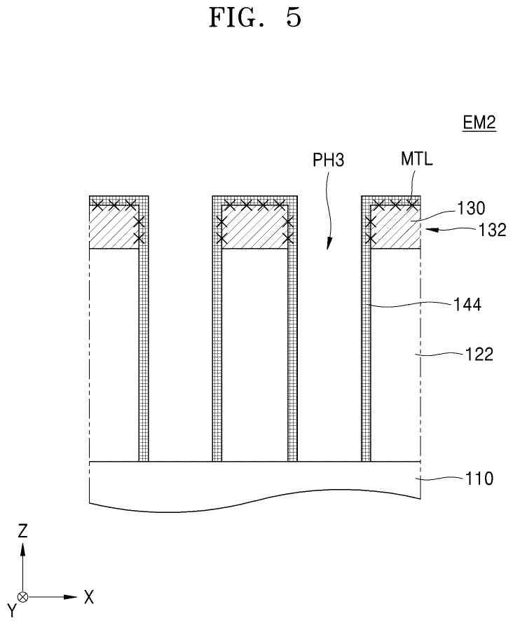

FIG. 5 is a cross-sectional view illustrating a method of manufacturing a semiconductor device EM2 according to some embodiments, the cross-sectional view showing a portion corresponding to the cross-section taken along the line X1-X1′ of FIG. 3. In FIG. 5, like reference numerals as in FIGS. 3 and 4A to 4D denote like elements, and repeated descriptions thereof are omitted.

Referring to FIG. 5, according to the same method described with reference to FIGS. 2 and 4A to 4B, the feature layer 120 may be formed on the first surface of the substrate 110 in operation P110, the mask pattern 130 may be formed on the feature layer 120 in operation S120, and then the surface of the mask pattern 130 is treated with the plasmafied first metal precursor gas, thus forming the surface modification layer including the metal particles MTL in operation P130.

Then, in operation P140, the feature pattern 122 may be formed by processing the feature layer 120 through the plasma etching process. During the plasma etching process stated above, an etching gas mixture including an etching gas and a second metal precursor gas may be used. In some embodiments, the gas mixture may be converted into plasma and guided to the semiconductor device EM2.

In some embodiments, operation P140 of forming the feature pattern 122 by removing a portion of the feature layer 120 may include forming a passivation layer 144 on the exposed surface of the semiconductor device EM2. In some embodiments, the partial removal of the feature layer 120 may temporally overlap the formation of the passivation layer 144. In some embodiments, the passivation layer 144 may be formed on the exposed inner sidewall of the feature layer 120 as the processed surface of the mask pattern 132 and a portion of the feature layer 120 are removed.

In some embodiments, the passivation layer 144 may be formed on the upper surface and the inner sidewall of the mask pattern 130 and the inner sidewall of the feature pattern 122. In some embodiments, the passivation layer 144 may be formed on the surface modification layer. For example, the passivation layer 144 may be formed to cover the metal particles MTL.

In some embodiments, a third pattern hole PH3 limited by the first surface of the substrate 110 and the passivation layer 144 on the inner sidewall of the feature pattern 122 may be defined.

In some embodiments, the passivation layer 144 may basically include a fluorocarbon-based polymer including carbon-carbon bonds (C—C bonds), carbon-fluorine bonds (C—F bonds), or carbon-hydrogen bonds (C—H bonds) and may include carbon-metal bonds (C-M bonds). Here, M refers to a metal atom in the second metal precursor gas. In some embodiments, the second metal precursor gas may be turned into plasma along with the etching gas and guided to the semiconductor device EM2, and the metal atoms in the second metal precursor gas may form the passivation layer 144 together with the fluorocarbon-based polymer derived from the etching gas. Accordingly, the passivation layer 144 is not removed during plasma etching and remains on the inner wall of the third pattern hole PH3 and the surface of the mask pattern 130, thereby configuring the feature pattern 122 with improved pattern characteristics.

In some embodiments, the metal of the second metal precursor gas may include Ti, Zr, Hf, V, Nb, Ta, Mo, W, or a combination thereof.

In some embodiments, the metal of the second metal precursor gas may be selected to improve the stabilization constant Ks. In some embodiments, the metal of the second metal precursor gas may include Zr, Hf, Nb, or a combination thereof. In some embodiments, the metal of the second metal precursor gas may be selected from the group consisting of Zr, Hf, Nb and combinations thereof and may be easily bonded to the fluorocarbon-based polymer to form the passivation layer 144, thereby enabling excellent etching resistance of the passivation layer 144.

Then, according to the method that is the same as or similar to that described with reference to FIG. 4D, the passivation layer 144, the surface modification layer including the metal particles MTL, and the mask pattern 130 may be removed in operation P150.

### Experimental Example 3

In operation P140, the bond formation energy of each metal type with respect to a fluorocarbon-based polymer was calculated to determine whether the metal of the second metal precursor gas is stably coupled to the fluorocarbon-based polymer and provides etching resistance. In operation P140, the sputtering yield of the fluorocarbon-based passivation layer 144 including the C-M bonds was calculated to determine whether the fluorocarbon-based passivation layer 144 including the C-M bonds has sufficient etching resistance. The stabilization constant Kₛ was obtained based on the bond formation energy and sputtering yield calculated.

The simulation was conducted by modeling the process, in which the feature layer 120 including SiO₂ is etched with the gas mixture including CF₄ and the second metal precursor gas, the simulation being performed under the condition that the second metal precursor gas was present at about 5 volume % with respect to the total volume of CF₄.

Table 3 below shows the results from the simulation, including the bond formation energy of metals to the fluorocarbon-based polymer, the sputtering yield of the fluorocarbon-based passivation layer 144 including the C-M bonds, and the stabilization constant Kₛ when the gas mixture including CF₄ and the second metal precursor gas was used.

TABLE 3

| | | Formation energy | Sputtering | Stabilization |
|---|---|---|---|---|
| | Metals | (eV) | yield | constant Ks |
| Embodiment 18 | Ti | 7.51 | 0.1873 | 40.0961 |
| Embodiment 19 | Zr | 12.42 | 0.1841 | 67.4633 |
| Embodiment 20 | Hf | 12.64 | 0.1828 | 69.1466 |
| Embodiment 21 | V | 7.13 | 0.1905 | 37.4278 |
| Embodiment 22 | Nb | 12.46 | 0.1869 | 66.6667 |
| Embodiment 23 | Ta | 4.18 | 0.1845 | 22.6558 |
| Embodiment 24 | Mo | 6.79 | 0.1916 | 35.4384 |
| Embodiment 25 | W | 4.77 | 0.1873 | 25.4672 |
| Comparative | — | — | 0.2198 | — |
| Example 3 | | | | |

Referring to Table 3, compared to Comparative Example 3 in which CF₄ is solely used as the etching gas without metals, it was found that the fluorocarbon-based passivation layer 144 in Embodiment 18 to Embodiment 25 has a relatively low sputtering yield, that is, relatively high etching resistance. In addition, referring to Embodiment 19, Embodiment 20, and Embodiment 22, it was identified that using Zr, Hf, and Nb leads to a relatively high stabilization constant Kₛ, compared to the use of other metals.

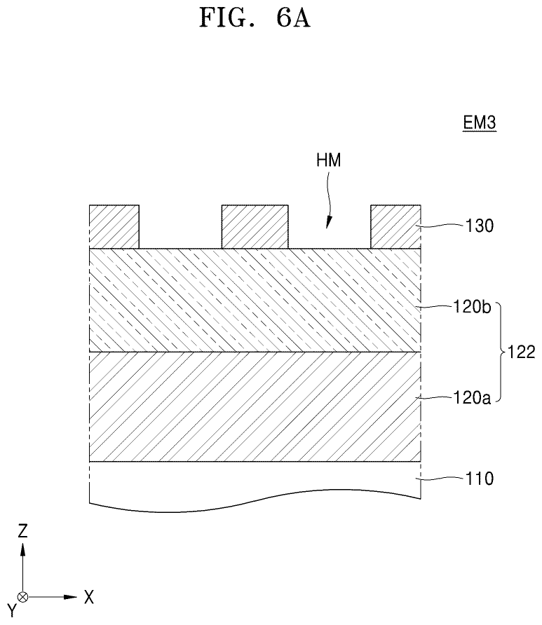

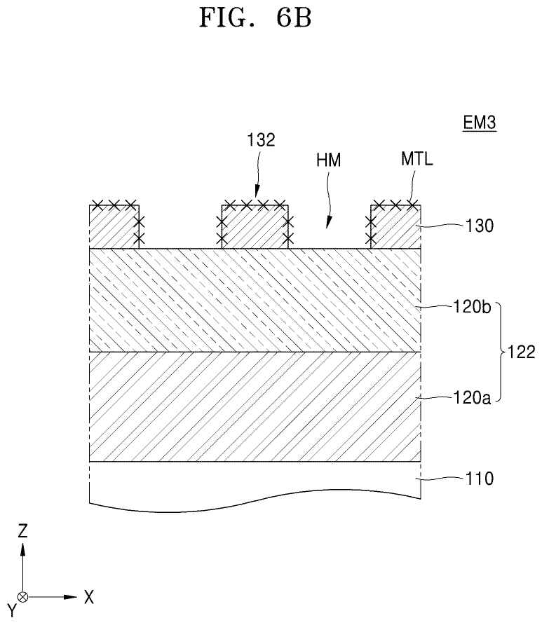

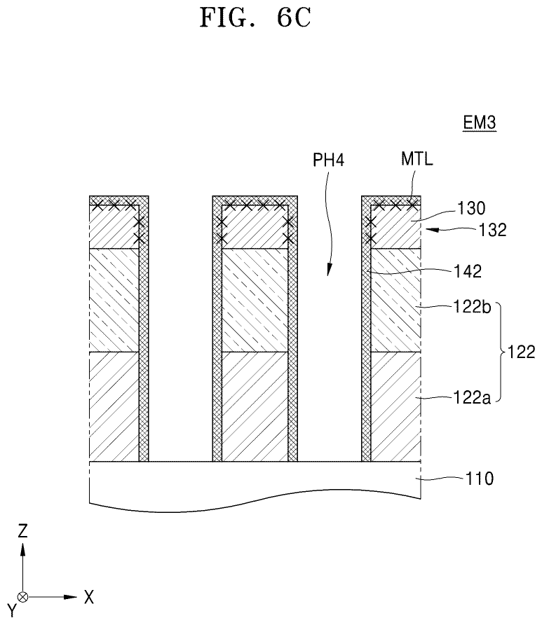

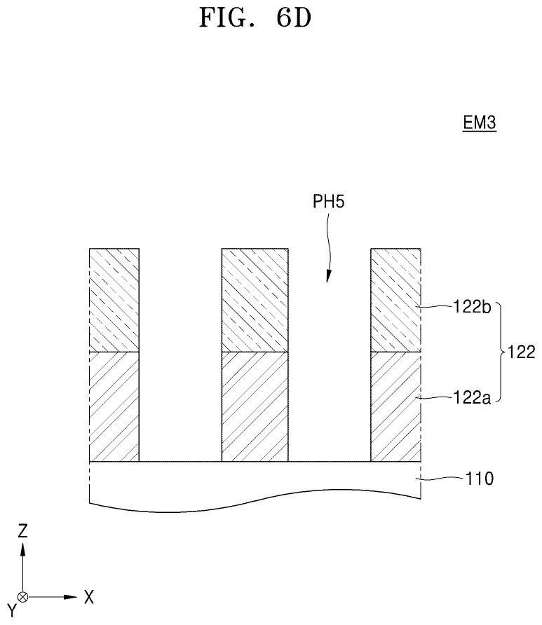

FIGS. 6A to 6D are cross-sectional views shown in process sequence illustrating a method of manufacturing a semiconductor device EM3 according to some embodiments, the cross-sectional views showing, in process sequence, a portion corresponding to the cross-section taken along the line X1-X1′ of FIG. 3. In FIGS. 6A to 6D, like reference numerals as in FIGS. 3 and 4A to 4D denote like elements, and repeated descriptions thereof are omitted.

The method of manufacturing the semiconductor device EM3 described with reference to FIGS. 6A to 6D is substantially the same as that for the semiconductor device EM3 described with reference to FIGS. 3 and 4A to 4D. However, FIGS. 6A to 6D differ in that a first unit feature layer 120a and a second unit feature layer 120b are sequentially formed to form the feature layer 120 in operation P110 and a first unit feature pattern 122a and a second unit feature pattern 122b are formed by processing the feature layer 120 in operation P140.

Referring to FIGS. 2 and 6A, in operation P110, the first unit feature layer 120a and the second unit feature layer 120b may be sequentially formed on the first surface of the substrate 110. For example, the first unit feature layer 120a and the second unit feature layer 120b may form the feature layer 120.

In some embodiments, the first unit feature layer 120a may include a material different from that of the second unit feature layer 120b. For example, the first unit feature layer 120a may include SiO, while the second unit feature layer 120b may include SiN.

FIG. 6A shows that the feature layer 120 includes two unit feature layers, that is, the first unit feature layer 120a and the second unit feature layer 120b, but one or more embodiments are not limited thereto. For example, the feature layer 120 may include three or more unit feature layers. In this case, at least some of the unit feature layers may include different materials.

Then, in operation P120, the mask pattern 130 may be formed on the upper surface of the second unit feature layer 120b. The method of forming the mask pattern 130 and the materials forming the same are substantially the same as those described with reference to FIG. 4A.

Referring to FIG. 6B, in operation P130, in the result of FIG. 6A, the surface of the mask pattern 130 may be treated using a plasmafied first metal precursor gas. According to embodiments, the first metal precursor gas may be converted into plasma and guided to the surface of the mask pattern 130, and the metal atoms MTL in the first metal precursor gas may be chemically bonded to the surface of the mask pattern 130. In some embodiments, the surface modification layer including the metal atoms MTL may be formed on the surface of the mask pattern 130. In some embodiments, by treating the surface of the mask pattern 130, a modified mask pattern 132 including the metal particles MTL may be formed. The metals of the first metal precursor gas are substantially the same as those described with refence to FIG. 6B.

In some embodiments, the mask pattern 130 may include a carbon-based material, for example, an ACL or a metal-doped carbon layer, and the metal of the surface modification layer may include Ti, Zr, Hf, V, Nb, Ta, Mo, W, or a combination thereof.

In some embodiments, the mask pattern 130 may include a silicon-based material, for example, polysilicon or silicon doped with metal, and the metal of the surface modification layer may include Zr, Hf, Nb, Ta, Mo, W, or a combination thereof.

Referring to FIGS. 2 and 6C, in the result of FIG. 6B, a feature layer may be processed using the surface-treated mask pattern 130, in operation P140. According to embodiments, a portion of each of the first unit feature layer 120a and the second unit feature layer 120b is removed through plasma etching using the plasmafied etching gas, thus forming the first unit feature pattern 122a and the second unit feature pattern 122b. The first unit feature pattern 122a and the second unit feature pattern 122b may form the feature pattern 122. During the plasma etching process, the mask pattern 130 and the surface modification layer may be provided as etch masks. In some embodiments, the plasma etching may be performed so that the first surface of the substrate 110 is partially exposed.

According to embodiments, processing the feature layer 120 may include forming the passivation layer 142 on the upper surface and the inner sidewall of the mask pattern 130 and the inner sidewall of the feature pattern 122. In some embodiments, the passivation layer 142 may be formed on the surface modification layer. For example, the passivation layer 142 may be formed to cover the metal particles MTL. In some embodiments, the partial removal of the feature layer 120 may temporally overlap the formation of the passivation layer 142. For example, the passivation layer 142 may be simultaneously formed to cover the surface of the mask pattern 130 and the exposed inner wall of the feature layer 120 as a portion of the feature layer 120 is removed.

In some embodiments, a fourth pattern hole PH4 limited by the first surface of the substrate 110 and the passivation layer 142 on the inner sidewall of the feature pattern 122 may be defined.

In some embodiments, the etching gas may include fluorocarbon, hydrofluorocarbon, a fluorine-based material including core elements other than carbon, or a combination thereof, and the specific example is the same as that described with reference to FIG. 4C.

Referring to FIGS. 2 and 6D, in operation P150, the passivation layer 142, the surface modification layer including the metal particles MTL, and the mask pattern 130 may be removed from the result of FIG. 6C. Accordingly, the first unit feature pattern 122a and the second unit feature pattern 122b that are sequentially stacked on the first surface of the substrate 110 may be formed.

According to embodiments, as the passivation layer 142 is removed, the inner sidewall of each of the first unit feature pattern 122a and the second unit feature pattern 122b may be exposed, and a fifth pattern hole PH5 defined by the inner sidewall of each of the first unit feature pattern 122a and the second unit feature pattern 122b and a portion of the first surface of the substrate 110 may be formed.

Although an exemplary method of manufacturing a semiconductor device has been described so far, it would be obvious to one of ordinary skill in the art that various modifications and changes may be made based on the description of FIGS. 1A to 6D within the scope of the inventive concept, allowing for the manufacture of semiconductor devices with modified and changed configurations.

While the inventive concept has been particularly shown and described with reference to embodiments thereof, it will be understood that various changes in form and details may be made therein without departing from the spirit and scope of the following claims.

What is claimed is:

1. A method of manufacturing a semiconductor device, the method comprising:
forming a mask pattern on a feature layer;
modifying a surface of the mask pattern by using a metal precursor gas that is plasmafied to provide a modified surface; and
etching the feature layer by using the mask pattern having the modified surface.

2. The method of claim 1, wherein the mask pattern comprises a carbon-based material, and
a metal of the metal precursor gas is selected from the group consisting of titanium (Ti), zirconium (Zr), hafnium (Hf), vanadium (V), niobium (Nb), tantalum (Ta), molybdenum (Mo), tungsten (W) and combinations thereof.

3. The method of claim 1, wherein the mask pattern comprises a silicon-based material, and
a metal of the metal precursor gas is selected from the group consisting of zirconium (Zr), hafnium (Hf), niobium (Nb), tantalum (Ta), molybdenum (Mo), tungsten (W) and combinations thereof.

4. The method of claim 1, wherein the etching of the feature layer comprises removing a portion of the feature layer using a plasmafied etching gas by using the mask pattern having the modified surface as an etch mask.

5. The method of claim 4, wherein the etching gas is selected from the group consisting of fluorocarbon, hydrofluorocarbon and combinations thereof.

6. The method of claim 1, wherein the metal precursor gas is a first metal precursor gas, and the etching of the feature layer comprises using a gas mixture that is plasmafied, and
the gas mixture comprises an etching gas and a second metal precursor gas.

7. The method of claim 6, wherein a metal of the second metal precursor gas is selected from the group consisting of zirconium (Zr), hafnium (Hf), niobium (Nb) and combinations thereof.

8. The method of claim 1, wherein the etching of the feature layer comprises
forming a feature pattern by removing a portion of the feature layer using the mask pattern having the modified surface as an etch mask; and
forming a passivation layer on an inner sidewall of the feature pattern and the surface of the mask pattern.

9. The method of claim 8, wherein the passivation layer comprises a fluorocarbon-based polymer comprising a carbon-metal bond.

10. The method of claim 8, wherein the removing of a portion of the feature layer temporally overlaps the forming of the passivation layer.

11. A method of manufacturing a semiconductor device, the method comprising:
forming a feature layer on a substrate;
forming a mask pattern on the feature layer;
modifying a surface of the mask pattern with a metal; and
forming a feature pattern by removing a portion of the feature layer using a gas mixture that is plasmafied,
wherein the gas mixture comprises an etching gas and a metal precursor gas.

12. The method of claim 11, wherein the etching gas is selected from the group consisting of fluorocarbon, hydrofluorocarbon, and combinations thereof, and
a metal of the metal precursor gas is selected from the group consisting of zirconium (Zr), hafnium (Hf), niobium (Nb) and combinations thereof.

13. The method of claim 11, wherein the metal precursor gas is selected from the group consisting of zirconium chloride, zirconium fluoride, bis(cyclopentadienyl)zirconium dichloride), bis(cyclopentadienyl)zirconium chloride hydride), zirconium tert-butoxide, tetrakis(2,4-pentanedionato)zirconium, tetrakis(dimethylamido)zirconium, tetrakis(ethylmethylamido)zirconium and combinations thereof.

14. The method of claim 11, wherein the metal precursor gas is selected from the group consisting of hafnium chloride, hafnium fluoride, bis(cyclopentadienyl)hafnium dichloride, tetrabenzylhafnium, hafnium trifluoromethanesulfonate, hafnium 2,4-pentanedionate, tetrakis(dimethylamido)hafnium, tetrakis(ethylmethylamido)hafnium and combinations thereof.

15. The method of claim 11, wherein the metal precursor gas is selected from the group consisting of niobium chloride, niobium fluoride, niobium ethoxide, cyclopentadienylniobium tetrachloride, tetrakis(2,2,6,6-tetramethyl-3,5-heptanedionato)niobium, tetrachlorobis(tetrahydrofuran)niobium, pentakis(dimethylamino)niobium, tris(diethylamido)(tert-butylimido)niobium and combinations thereof.

16. The method of claim 11, wherein the forming of the feature pattern comprises forming a passivation layer on an inner sidewall of the feature pattern and the surface of the mask pattern, and
the passivation layer comprises a fluorocarbon-based polymer comprising a carbon-metal bond.

17. A method of manufacturing a semiconductor device, the method comprising:
forming a mask pattern on a feature layer;
modifying a surface of the mask pattern with a first metal precursor gas that is plasmafied;
forming a feature pattern by
converting a gas mixture into plasma, the gas mixture comprising an etching gas and a second metal precursor gas, and
removing a portion of the feature layer by using the mask pattern as an etch mask;
forming, on an inner sidewall of the feature pattern and the surface of the mask pattern, a fluorocarbon-based passivation layer comprising a carbon-metal bond; and
removing the mask pattern and the passivation layer,
wherein the removing of the portion of the feature layer temporally overlaps the forming of the passivation layer.

18. The method of claim 17, wherein the mask pattern comprises a carbon-based material, and
a metal of the first metal precursor gas is selected from the group consisting of titanium (Ti), zirconium (Zr), hafnium (Hf), vanadium (V), niobium (Nb), tantalum (Ta), molybdenum (Mo), tungsten (W) and combinations thereof.

19. The method of claim 17, wherein the mask pattern comprises a silicon-based material, and
a metal of the first metal precursor gas is selected from the group consisting of zirconium (Zr), hafnium (Hf), niobium (Nb), tantalum (Ta), molybdenum (Mo), tungsten (W) and combinations thereof.

20. The method of claim 17, wherein a metal of the second metal precursor gas is selected from the group consisting of zirconium (Zr), hafnium (Hf), niobium (Nb) and combinations thereof.
